(19) United States
(12) Patent Application Publication
(10) Pub. No.: US 2026/0173249 A1
(43) Pub. Date: Jun. 18, 2026

(54) THERMAL CONNECTIONS WITHIN A DEVICE ENCLOSURE TO IMPROVE THERMAL DISSIPATION

(71) Applicant: SK Hynix NAND Product Solutions Corp. (dba Solidigm), Rancho Cordova, CA (US)

(72) Inventors: Hardeep Singh, Vancouver (CA); Sanket Nangare, Folsom, CA (US); Wayne Gregory, Sacramento, CA (US); Andrew Morning-Smith, Vancouver (CA)

(21) Appl. No.: 18/982,665

(22) Filed: Dec. 16, 2024

(51) Int. Cl. H05K 1/02; H05K 7/20

(52) U.S. Cl. CPC H05K 1/0204; H05K 7/20409

(57) ABSTRACT

A device, printed circuit board (PCB), and enclosure to house the PCB, wherein the device includes the PCB and the enclosure. The PCB includes a top surface, a bottom surface, and the device includes circuitry disposed on the top surface or the bottom surface of the PCB. The enclosure includes a top cover, a bottom cover, and one or more thermally-conductive poles, each of which thermally couple the top cover and the bottom cover to cause heat transfer between the top cover and the bottom cover, and each pole is arranged in a respective opening of the PCB such that there is no contact between any of the thermally-conductive poles and the PCB.

### TECHNICAL FIELD

The present disclosure is directed to thermal connections and more particularly to thermal connections internal an enclosure housing a device.

### SUMMARY

In accordance with the present disclosure, devices, printed circuit boards (PCBs), and enclosures are provided to improve the thermal distribution between a top cover and bottom cover of a respective enclosure that is configured to house a respective PCB. The device may include a PCB, circuitry that is disposed on one or more of a top surface or bottom surface of the PCB, and an enclosure to house the PCB. The enclosure that houses the PCB includes a top cover and a bottom cover, and at least one or more thermally-conductive thermal connections (e.g., thermally-conductive poles, thermally-conductive slugs with thermally-conductive pole pairs, or thermally-conductive connectors) to cause heat transfer between the top cover and the bottom cover. The devices, PCBs, and enclosures disclosed herein promote thermal transfer between the top cover and the bottom cover to limit or reduce thermal throttling of the circuitry and improve the thermal performance of the enclosure. The circuitry of the device may include electrical components, one or more of which may generate heat when in operation. The thermal connections (e.g., thermally-conductive poles, thermally-conductive slugs with thermally-conductive pole pairs, or thermally-conductive connectors) may be arranged based on each respective location of the electrical components of the circuitry. The thermal connections (e.g., thermally-conductive poles, thermally-conductive slugs with thermally-conductive pole pairs, or thermally-conductive connectors) are arranged within the enclosure such that each thermal connection is in thermal contact with the top cover and the bottom cover. The devices, PCBs, and enclosures disclosed herein are provided to promote thermal transfer between the top cover and the bottom cover to limit or reduce thermal throttling of the circuitry and improve the thermal performance of the enclosure.

### BRIEF DESCRIPTION OF THE DRAWINGS

The following description includes discussion of figures having illustrations given by way of example of implementations of embodiments of the disclosure. The drawings should be understood by way of example, and not by way of limitation. As used herein, references to one or more “embodiments” are to be understood as describing a particular feature, structure, and/or characteristic included in at least one implementation. Thus, phrases such as “in one embodiment” or “in an alternate embodiment” appearing herein describe various embodiments and implementations, and do not necessarily all refer to the same embodiment. However, they are also not necessarily mutually exclusive.

FIG. 1 shows an illustrative cross-sectional view diagram of a device with a thermally-conductive pole, in accordance with some embodiments of the present disclosure;

FIG. 2 shows an illustrative cross-sectional diagram of a device with a thermally-conductive pole pair, in accordance with some embodiments of the present disclosure;

FIG. 3 shows an illustrative cross-sectional diagram of a device with a thermally-conductive connector, in accordance with some embodiments of the present disclosure;

FIG. 4 shows an illustrative cross-sectional diagram of a device with another thermally-conductive connector, in accordance with some embodiments of the present disclosure;

FIG. 5 shows an illustrative perspective, partly-sectional, view diagram of an enclosure with thermal interface material (TIM), in accordance with some embodiments of the present disclosure;

FIG. 6 shows an illustrative cross-sectional diagram of another device including TIM, in accordance with some embodiments of the present disclosure;

FIG. 7 shows an illustrative perspective, partly sectional, view diagram of a device with thermally-conductive poles, similar to the device of FIG. 1, in accordance with some embodiments of the present disclosure;

FIG. 8 shows an illustrative cross-sectional view diagram of the device with thermally-conductive poles similar to the device of FIG. 7, in accordance with some embodiments of the present disclosure;

FIG. 9 shows an illustrative diagram for temperature distributions along the enclosure of a device without thermal connections within the enclosure, in accordance with some embodiments of the present disclosure; and

FIG. 10 shows an illustrative diagram for temperature distributions along the enclosure of a device with thermal connections within the enclosure, in accordance with some embodiments of the present disclosure.

### DETAILED DESCRIPTION

In accordance with the present disclosure, devices, PCBs and enclosures are provided for improved thermal distribution between a top cover and bottom cover of a respective enclosure. Each device disclosed herein includes a PCB, an enclosure including a top cover, bottom cover, and thermal connections (e.g., thermally-conductive poles, thermally-conductive slugs with thermally-conductive pole pairs, or thermally-conductive connectors), and thermal interface material (TIM). Each device disclosed herein also includes circuitry, which is arranged on one or both of a top surface or bottom surface of the PCB. The enclosure disclosed herein may be any suitable thermally-conductive housing of circuitry with any suitable form factor. For example, the device may include an enclosure containing one or more integrated circuits or dies. In some embodiments, the top cover and bottom cover of the enclosure are thermally conductive to act as heat sinks, each dissipating heat generated from the circuitry while in operation. Any heat generated by the circuitry may refer to the thermal output of electrical components of the circuitry (e.g., high-performance integrated circuit chips or cores) disposed on the PCB.

The thermal connections (e.g., thermally-conductive poles, thermally-conductive slugs with thermally-conductive pole pairs, or thermally-conductive connectors) are arranged within the enclosure to promote heat transfer between the top cover and the bottom cover of the enclosure. In some embodiments, the thermal connections (e.g., thermally-conductive poles, thermally-conductive slugs with thermally-conductive pole pairs, or thermally-conductive connectors) are arranged within the enclosure based on the respective location of the electrical components of the circuitry. Each thermal connection (e.g., thermally-conductive poles, thermally-conductive slugs with thermally-conductive pole pairs, or thermally-conductive connectors) is arranged to be in thermal contact with each of (1) top cover and (2) bottom cover of the enclosure to cause heat transfer between the two covers of the enclosure.

Each of the thermal connections (e.g., thermally-conductive poles, thermally-conductive slugs with thermally-conductive pole pairs, or thermally-conductive connectors) and the enclosure (e.g., top cover and bottom cover) are thermally conductive. In some embodiments, heat generated from circuitry (e.g., electrical components on PCB) in operation is transferred to the enclosure in such a way that results in uneven thermal distribution. The thermal connections (e.g., thermally-conductive poles, thermally-conductive slugs with thermally-conductive pole pairs, or thermally-conductive connectors) are thermally conductive to promote heat transfer between the top cover and the bottom cover of the enclosure, thus promoting thermal load balancing between the covers of the enclosure. Each of the top cover and bottom cover is thermally conductive to dissipate heat generated from the circuitry of the device in operation.

The circuitry is arranged on one or both of a top surface and a bottom surface of the printed circuit board (PCB), the circuitry including electrical components, at least one of which is a heat-generating electrical component. The electrical components of the circuitry may be any suitable high-performance electrical component (e.g., an integrated circuit device, such as an application-specific integrated circuit (ASIC) device). In some embodiments, the PCB includes multiple dielectric layers, on which the electrical components may be mounted. In some embodiments, a TIM may be positioned between a respective heat-generating electrical component and a respective thermally-conductive plate of the thermal spreader layer.

In some embodiments, the device includes multiple thermal connections (e.g., one or more of each of thermally-conductive poles, thermally-conductive slugs with thermally-conductive pole pairs, or thermally-conductive connectors) to promote thermal transfer between the top cover and the bottom cover to limit or reduce thermal throttling of the circuitry and improve thermal performance of the enclosure.

For purposes of brevity and clarity, the features of the disclosure described herein are in the context of a device with circuitry disposed on a PCB that is housed by an enclosure. However, the principles of the present disclosure may be applied to any other suitable context in which an enclosure houses a PCB on which circuitry is disposed.

In particular, the present disclosure provides devices, PCBs, and enclosures, where the device provided includes thermal connections (e.g., thermally-conductive poles, thermally-conductive slugs with thermally-conductive pole pairs, or thermally-conductive connectors) to cause heat transfer between the top cover and the bottom cover of the enclosure. The devices, PCBs, and enclosures disclosed herein promote thermal transfer between the top cover and the bottom cover of the enclosure to limit or reduce thermal throttling of the circuitry and improve the thermal performance of the enclosure.

In some embodiments, the circuitry of the device may include any suitable processing circuitry, which may include any suitable processing chip (e.g., an application-specific integrated circuit (ASIC) chip) or processing core.

In some embodiments, the device may include a circuitry that functions as a storage device system (e.g., a solid-state drive (SSD) storage system), which includes a storage device such as a solid-state drive device.

An SSD is a data storage device that uses integrated circuit assemblies as memory to store data persistently. SSDs have no moving mechanical components, and this feature distinguishes SSDs from traditional electromechanical magnetic disks, such as hard disk drives (HDDs) or floppy disks, which contain spinning disks and movable read/write heads. Compared to electromechanical disks, SSDs are typically more resistant to physical shock, run silently, have lower access time, and less latency.

Many types of SSDs use NAND-based flash memory which retains data without power and includes a type of non-volatile storage technology. Quality of Service (QoS) of an SSD may be related to the predictability of low latency and consistency of high input/output operations per second (IOPS) while servicing read/write input/output (I/O) workloads. This means that the latency or the I/O command completion time needs to be within a specified range without having unexpected outliers. Throughput or I/O rate may also need to be tightly regulated without causing sudden drops in performance levels.

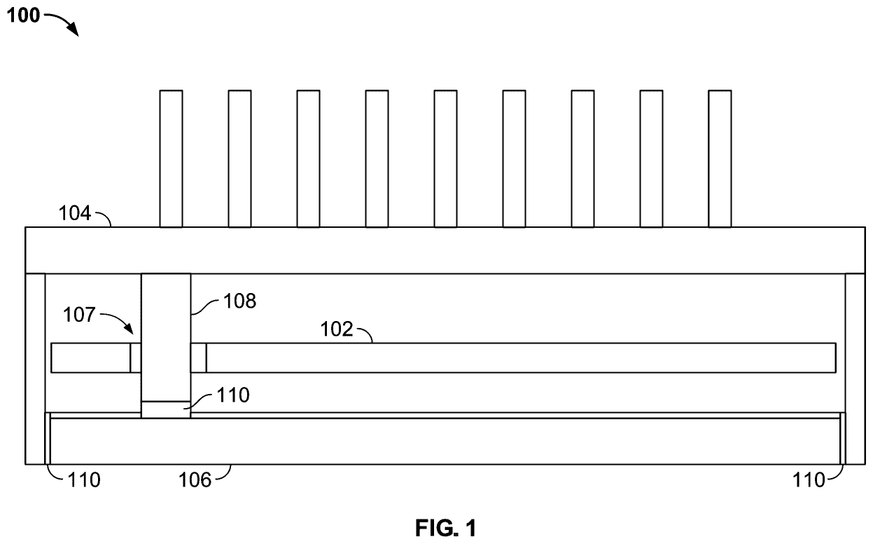

The subject matter of this disclosure may be better understood by reference to FIGS. 1-10.

FIG. 1 shows an illustrative cross-sectional view diagram of a device 100 with a thermally-conductive pole 108, in accordance with some embodiments of the present disclosure. Device 100 includes PCB 102, an enclosure (e.g., top cover 104, bottom cover 106, and thermally-conductive pole 108), and thermal interface material (TIM) 110. Device 100 may be defined as having (1) a top side where a top surface of PCB 102 and top cover 104 of the enclosure are disposed, and (2) a bottom side where a bottom surface of PCB 102 and bottom cover 106 of the enclosure are disposed. Device 100 also includes circuitry (not shown), which is arranged on the top surface or the bottom surface of the PCB 102, or both.

In some embodiments, the circuitry includes at least one electrical component, any respective one of which may generate heat while in operation. In some implementations, the thermally-conductive poles 108 are disposed within the enclosure based on each respective location of the electrical components. Each of the thermally-conductive poles 108 is arranged to be in thermal contact with each of (1) top cover 104 and (2) bottom cover 106) to cause heat transfer between top cover 104 and bottom cover 106.

Additionally, PCB 102 includes holes (e.g., hole 107), through which respective thermally-conductive poles 108 extend. Each respective hole (e.g., hole 107) in PCB 102 is arranged such that a respective thermally-conductive pole (e.g., thermally-conductive pole 108) extends through the hole (e.g., hole 107) without coming into thermal contact with PCB 102 to reduce thermal transfer from the respective thermally-conductive 108 to the PCB 102. The holes 107 may be filled with any thermally-insulative material (e.g. a pocket of air). The holes 107 are arranged in order to reduce the direct thermal transfer from each thermally-conductive pole 108 by insulating the thermally-conductive pole 108 from being in thermal contact with PCB 102. With the arranged holes 107, heat may transfer between the top cover 104 and bottom cover 106 along the thermally-conductive pole 108.

In some embodiments, each of the thermally-conductive poles 108 is a part of one of the top cover 104 or the bottom cover 106. In some embodiments, TIM 110 is disposed between the thermally-conductive pole 108 and one of (1) the top cover 104 and (2) the bottom cover 106 to promote heat transfer between the thermally-conductive pole 108 and one of (1) top cover 104 and (2) the bottom cover 106. In some embodiments, TIM 110 is disposed between top cover 104 and bottom cover 106 to further promote heat transfer between top cover 104 and bottom cover 106.

Each of the thermally-conductive poles 108 and the enclosure (e.g., top cover 104 and bottom cover 106) are thermally conductive. In some embodiments, heat generated from circuitry (e.g., electrical components on PCB 102) in operation is transferred to the enclosure (e.g., top cover 104 and bottom cover 106) in such a way that results in uneven thermal distribution. For example, the top surface of PCB 102 may include a greater concentration of electrical components than the bottom surface of PCB 102, which may lead to a greater amount of transferred heat from the top surface of PCB 102 to the top cover 104 than an amount of transferred heat from the bottom surface of PCB 102 to the bottom cover 106. The thermally-conductive poles 108 are thermally conductive to promote heat transfer between the top cover 104 and the bottom cover 106, thus promoting thermal load balancing between the top cover 104 and the bottom cover 106. Each of the top cover 104 and bottom cover 106 are thermally conductive to dissipate heat generated from the circuitry of the device in operation. Although not shown in FIG. 1, device 100 may include further thermal connections or layers that promote heat transfer from circuitry (e.g., electrical components) on a respective side of PCB 102 to the enclosure (e.g., top cover 104 or bottom cover 106).

It will be understood that, while device 100 depicts an embodiment in which PCB 102 is encapsulated by the enclosure (e.g., top cover 104 and bottom cover 106) in accordance with the present disclosure, any other suitable thermally-conductive housing may be implemented in a similar manner. Additionally, although device 100 depicts an embodiment in which there is one thermally-conductive pole 108 extending through one hole 107, device 100 may include more than one thermally-conductive pole 108 extending through respective holes 107.

For purposes of clarity and brevity, and not by way of limitation, the present disclosure is provided in the context of a device 100, which provides the features and functionalities disclosed herein. Device 100 may be at least partially implemented with, for example, a server device or storage device.

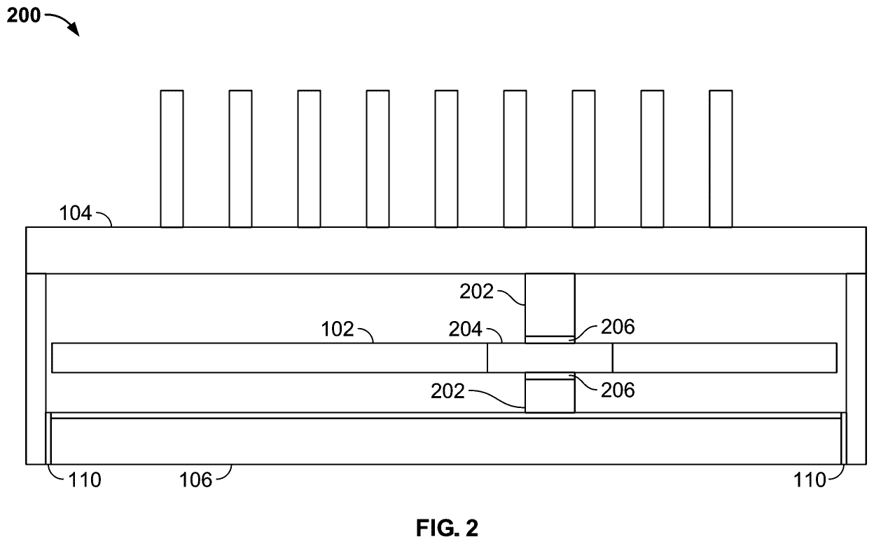

FIG. 2 shows an illustrative cross-sectional diagram of a device 200 with a thermally-conductive pole pair 202 and thermally-conductive slug 204, in accordance with some embodiments of the present disclosure. Device 200 includes PCB 102 with thermally-conductive slug 204, an enclosure (e.g., top cover 104, bottom cover 106, and thermally-conductive pole pair 202), and TIM 206. Similar to device 100 in FIG. 1, device 200 may be defined as having (1) a top side where the top surface of PCB 102 and top cover 104 of the enclosure are disposed, and (2) a bottom side where a bottom surface of PCB 102 and bottom cover 106 of the enclosure are disposed. Device 200 also includes circuitry (not shown), which is arranged on the top surface or the bottom surface of the PCB 102, or both.

In some embodiments, the circuitry includes at least one electrical component, any respective one of which may generate heat while in operation. In some implementations, thermally-conductive pole pairs 202 are disposed within the enclosure based on each respective location of the electrical components. Each respective one of the thermally-conductive pole pairs 202 may include (1) a first thermally-conductive pole arranged in thermal contact with top cover 104 and a respective thermally-conductive slug 204 and (2) a second thermally-conductive pole arranged in thermal contact with bottom cover 106 and the respective thermally-conductive slug 204 to cause heat transfer between top cover 104 and bottom cover 106. In some embodiments, the first thermally-conductive pole is part of the top cover 104 and the second thermally-conductive pole is a part of the bottom cover 106. In some implementations, TIM 206 is disposed between a respective thermally-conductive slug 204 and each thermally-conductive pole of a respective thermally-conductive pole pair 202.

Each thermally-conductive slug 204 may be any thermally-conductive material (e.g., copper) disposed on and/or through the layers of PCB 102 such that heat may be transferred between the top side and the bottom side of the PCB 102. In some embodiments, the thermally-conductive slug 204 is thermally coupled to one or more electrical components of the circuitry (not shown) via conductive traces disposed within the layers of PCB 102.

Each of the pole pairs 202, slugs 204 and the enclosure (e.g., top cover 104 and bottom cover 106) are thermally conductive. In some embodiments, the thermally-conductive pole pairs 202 are thermally conductive to promote heat transfer between the top cover 104 and the bottom cover 106 through the thermally-conductive slug 204, thus promoting thermal load balancing between the top cover 104 and the bottom cover 106.

It will be understood that, while device 200 depicts an embodiment in which PCB 102 is encapsulated by the enclosure (e.g., top cover 104 and bottom cover 106) in accordance with the present disclosure, any other suitable thermally-conductive housing may be implemented in a similar manner. Additionally, although device 200 depicts an embodiment in which there is one thermally-conductive pole pair 202 thermally coupled to thermally-conductive slug 204, device 200 may include more than one thermally-conductive pole pair 202 with more than one thermally-conductive slug 204.

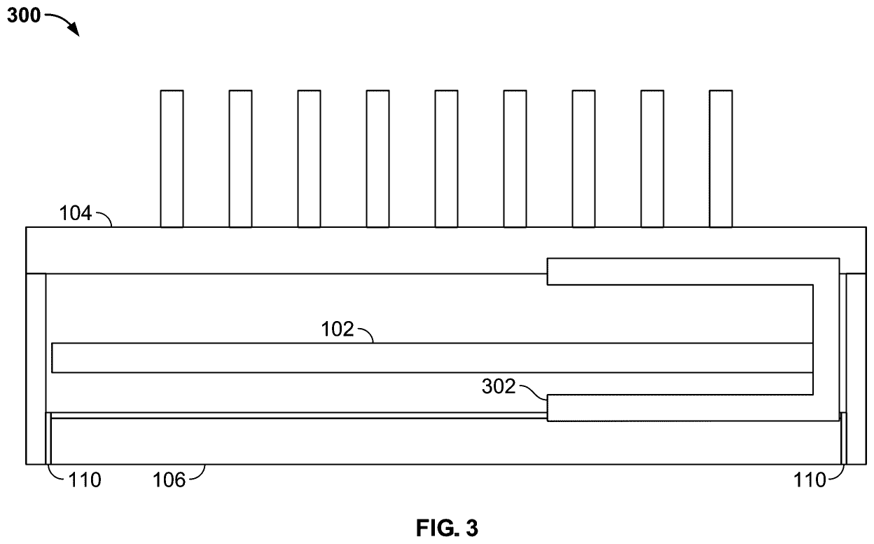

FIG. 3 shows an illustrative cross-sectional diagram of a device 300 with a thermally-conductive connector 302, in accordance with some embodiments of the present disclosure. Device 300 includes PCB 102, and an enclosure (e.g., top cover 104, bottom cover 106, and thermally-conductive connector 302). Device 300 also includes circuitry (not shown), which is arranged on the top surface or the bottom surface of the PCB 102, or both.

In some implementations, thermally-conductive connectors 302 are disposed within the enclosure based on each respective location of the electrical components of circuitry disposed on PCB 102. Each of the thermally-conductive connectors 302 may include (1) a first thermally-conductive member thermally coupled to top cover 104 and wherein the first thermally-conductive member extends, in a first direction parallel to top cover 104, to an edge of the PCB 102, (2) a second thermally-conductive member thermally coupled to the first thermally-conductive member and wherein the second thermally-conductive member is arranged in a respective opening disposed between the edge of the PCB 102 and the enclosure such that there is no contact between the second thermally-conductive member and the PCB 102, and (3) a third thermally-conductive member thermally coupled to each of the second thermally-conductive member and bottom cover 106, the third thermally-conductive member extending in a third direction parallel to bottom cover 106 and away from the edge of the PCB 102.

Each of the connectors 302 and the enclosure (e.g., top cover 104 and bottom cover 106) are thermally conductive. In some embodiments, the thermally-conductive connectors 302 are thermally conductive to promote heat transfer between the top cover 104 and the bottom cover 106 through the opening disposed between the edge of the PCB 102 and the enclosures, thus promoting thermal load balancing between the top cover 104 and the bottom cover 106.

It will be understood that, while device 300 depicts an embodiment in which PCB 102 is encapsulated by the enclosure (e.g., top cover 104 and bottom cover 106) in accordance with the present disclosure, any other suitable thermally-conductive housing may be implemented in a similar manner. Additionally, although device 300 depicts an embodiment in which there is one thermally-conductive connector 302, device 300 may include more than one thermally-conductive connector 302.

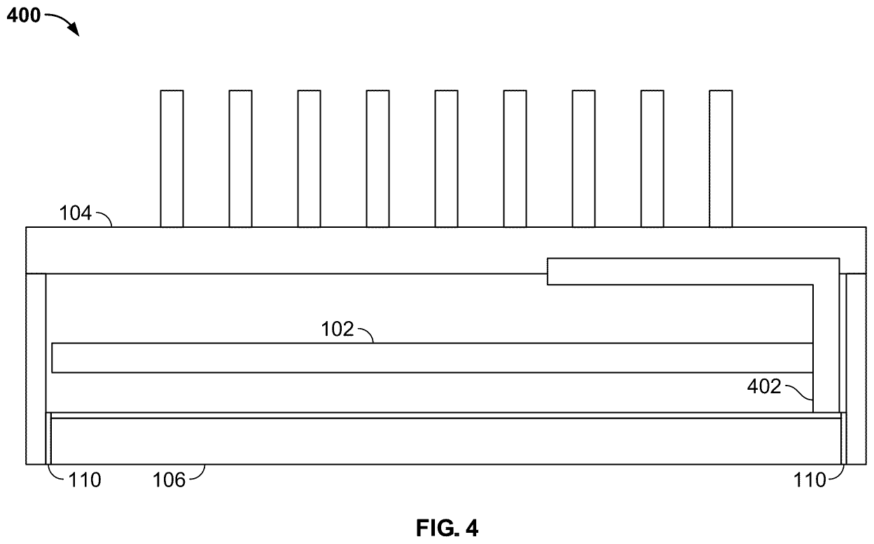

FIG. 4 shows an illustrative cross-sectional diagram of a device 400 with another thermally-conductive connector 402, in accordance with some embodiments of the present disclosure. Device 400 includes PCB 102, and an enclosure (e.g., top cover 104, bottom cover 106, and thermally-conductive connector 402). Device 400 also includes circuitry (not shown), which is arranged on the top surface or the bottom surface of the PCB 102, or both.

In some implementations, thermally-conductive connectors 402 are disposed within the enclosure based on each respective location of the electrical components of circuitry disposed on PCB 102. Each of the thermally-conductive connectors 402 may include (1) a first thermally-conductive member thermally coupled to top cover 104 and wherein the first thermally-conductive member extends, in a first direction parallel to top cover 104, to an edge of the PCB 102, and (2) a second thermally-conductive member thermally coupled to the first thermally-conductive member and bottom cover 106 wherein the second thermally-conductive member is arranged in a respective opening disposed between the edge of the PCB 102 and the enclosure such that there is no contact between the second thermally-conductive member and the PCB 102.

Each of the connectors 402 and the enclosure (e.g., top cover 104 and bottom cover 106) are thermally conductive. In some embodiments, the thermally-conductive connectors 402 are thermally conductive to promote heat transfer between the top cover 104 and the bottom cover 106 through the opening disposed between the edge of the PCB 102 and the enclosures, thus promoting thermal load balancing between the top cover 104 and the bottom cover 106.

It will be understood that, while device 400 depicts an embodiment in which PCB 102 is encapsulated by the enclosure (e.g., top cover 104 and bottom cover 106) in accordance with the present disclosure, any other suitable thermally-conductive housing may be implemented in a similar manner. Additionally, although device 400 depicts an embodiment in which there is one thermally-conductive connector 402, device 400 may include more than one thermally-conductive connector 402.

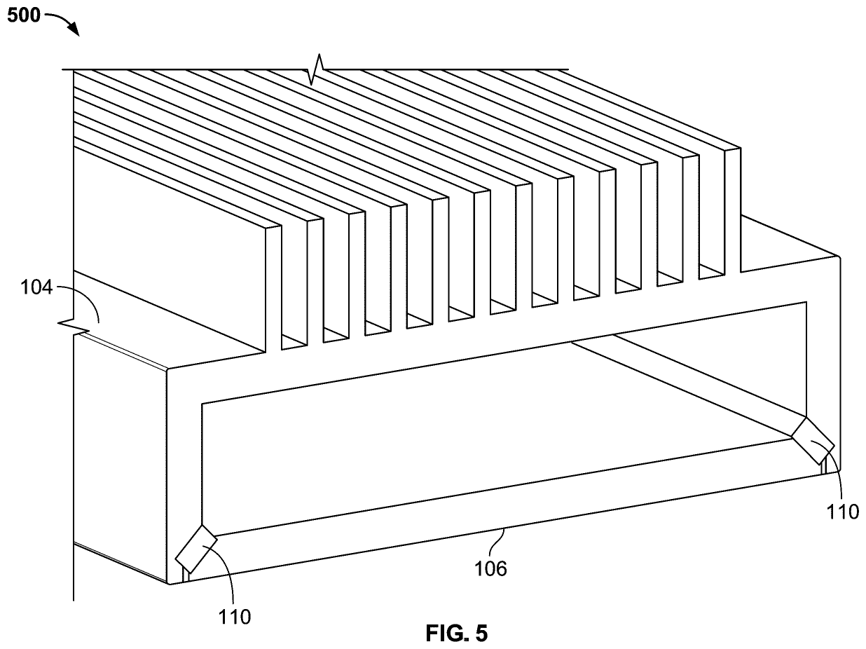

FIG. 5 shows an illustrative perspective, partly-sectional, view diagram of an enclosure 500 with TIM 110 disposed between top cover 104 and bottom cover 106, in accordance with some embodiments of the present disclosure. TIM 110 is disposed between top cover 104 and bottom cover 106 to further promote heat transfer between top cover 104 and bottom cover 106.

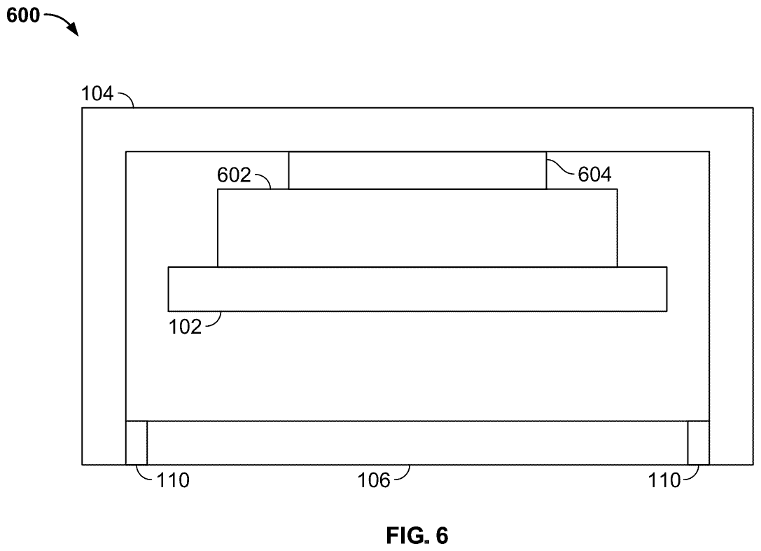

FIG. 6 shows an illustrative cross-sectional diagram of a device 600 including TIM 604, in accordance with some embodiments of the present disclosure. Device 600 includes PCB 102 onto which circuitry 602 is mounted, enclosure (e.g., top cover 104 and bottom cover 106), and TIM 604 disposed between circuitry 602 and the top cover 104. TIM 604 is disposed between circuitry 602 and top cover 104 to promote heat transfer from circuitry 602 (e.g., electrical components) to the enclosure. In some embodiments, TIM 110 is disposed between top cover 104 and bottom cover 106 to promote heat transfer between top cover 104 and bottom cover 106 to improve thermal load balancing of the enclosure.

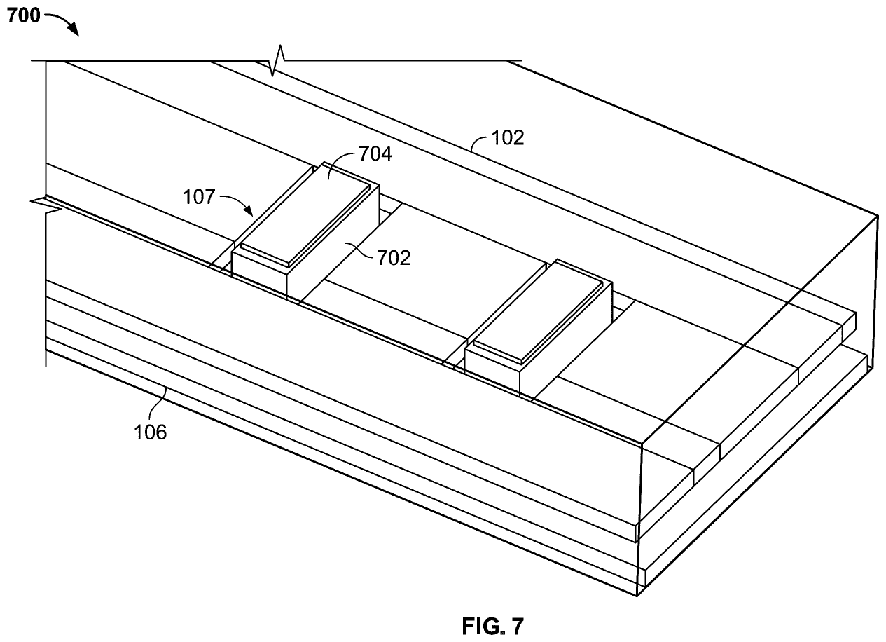

FIG. 7 shows an illustrative perspective, partly sectional, view diagram of a device 700 with thermally-conductive poles (e.g., including pedestal 702), similar to the device of FIG. 1, in accordance with some embodiments of the present disclosure. Device 700 includes PCB 102, an enclosure (e.g., top cover (not shown), bottom cover 106, and pedestals 702), and TIM 704. Device 700 may be defined as having (1) a top side where a top surface of PCB 102 and the top cover of the enclosure are disposed, and (2) a bottom side where a bottom surface of PCB 102 and bottom cover 106 of the enclosure are disposed. Device 700 also includes circuitry (not shown), which is arranged on the top surface or the bottom surface of the PCB 102, or both. Although FIG. 7 depicts embodiments of device 700 with respective pedestals 702 extending through holes 108 of PCB 102, each thermally-conductive pole extending through a respective hole 107 includes a first pedestal (e.g., pedestal 702), a second pedestal (not shown), and TIM 704 to thermally couple the first pedestal (e.g., pedestal 702) and the second pedestal.

PCB 102 includes holes (e.g., hole 107), through which respective thermally-conductive poles (e.g., including pedestal 702 and TIM 704) extend. Each respective hole (e.g., hole 107) in PCB 102 is arranged such that a respective thermally-conductive pole (e.g., including pedestal 702 and TIM 704) extends through the hole (e.g., hole 107) without coming into thermal contact with PCB 102 to reduce thermal transfer from the respective thermally-conductive (e.g., including pedestal 702) to the PCB 102. Holes 107 may be filled with any thermally-insulative material (e.g. a pocket of air). The holes 107 are arranged in order to reduce the direct thermal transfer from each thermally-conductive pole (e.g., at least pedestal 702) by insulating the thermally-conductive pole from being in thermal contact with PCB 102. With the arranged holes 107, heat may transfer between the top cover 104 and bottom cover 106 along the thermally-conductive pole.

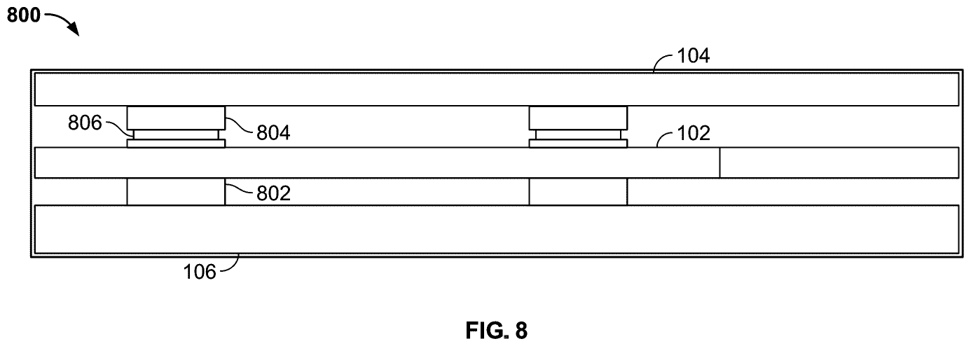

FIG. 8 shows an illustrative cross-sectional view diagram of device 800 with thermally-conductive poles (e.g., first pedestal 802, second pedestal 804, and TIM 806), similar to the device 700 of FIG. 7, in accordance with some embodiments of the present disclosure. In some embodiments, each first pedestal 802 is a part of the bottom cover 106 and each second pedestal is part of the top cover 104. In some embodiments, TIM 806 is disposed between the first pedestal 802 and second pedestal 804 to promote heat transfer between the top cover 104 and the bottom cover 106 using the thermally conductive poles (e.g., first pedestal 802, second pedestal 804, and TIM 806). Each of the first pedestals 802, the second pedestals 804, and the enclosure (e.g., top cover 104 and bottom cover 106) are thermally conductive.

It will be understood that, while device 800 depicts an embodiment in which PCB 102 is encapsulated by the enclosure (e.g., top cover 104 and bottom cover 106) in accordance with the present disclosure, any other suitable thermally-conductive housing may be implemented in a similar manner. Additionally, although device 800 depicts an embodiment in which there are two thermally-conductive poles (e.g., first pedestal 802, second pedestal 804, and TIM 806) extending through respective holes (not shown), device 800 may include more than two thermally-conductive poles (e.g., first pedestal 802, second pedestal 804, and TIM 806) extending through respective holes.

FIG. 9 shows an illustrative diagram for temperature distributions along the top cover 104 and bottom cover 106 of the enclosure of device 900 without thermal connections (e.g., one or more of (1) thermally-conductive poles 108, (2) thermally-conductive slugs and thermally-conductive pole pairs, or (3) thermally-conductive connectors such as a thermally-conductive connector 302 or thermally-conductive connector 402) within the enclosure, in accordance with some embodiments of the present disclosure. First area 902 of device 900 includes a hot-spot, such that the surface temperature of the bottom cover 106 of the enclosure is 105° C., while second area 904 of the top cover 103 of the enclosure has a surface temperature ranging from 65.6° C. to 72.6° C. This difference in respective surface temperatures of the first area 902 and the second area 904 indicates that the enclosure of the device 900 is providing poor thermal distribution of heat generated within the device 900. In some embodiments, the hot-spot at first area 902 may indicate an area at which a source (e.g., one or more electrical components on PCB 102) is generating heat within the device 900.

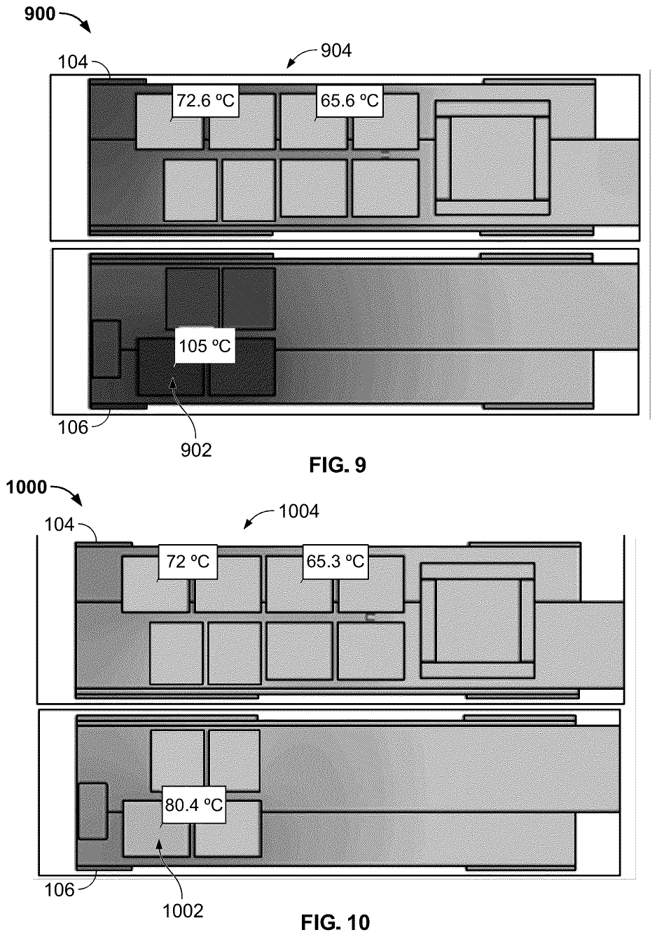

FIG. 10 shows an illustrative diagram for temperature distributions along the top cover 104 and bottom cover 106 of the enclosure of device 1000 with thermal connections (e.g., one or more of (1) thermally-conductive poles 108, (2) thermally-conductive slugs and thermally-conductive pole pairs, or (3) thermally-conductive connectors such as a thermally-conductive connector 302 or thermally-conductive connector 402) within the enclosure, in accordance with some embodiments of the present disclosure. As shown in FIG. 10 the external temperature of first area 1002 of the bottom cover 106 is 80.6° C., and the external temperature of second area 1004 ranges from 65.5° C. to 72° C. This diagram of the temperature distributions shows an improved thermal distribution along the top cover 104 and bottom cover 106 of device 1000 when compared to the thermal distribution of device 900.

The illustrative diagrams for temperature distributions along the top cover 104 and bottom cover 106 of the enclosure of (a) device 900 without thermal connections within the enclosure, and (b) device 1000 with thermal connections within the enclosure include example temperatures that are provided for illustrative purposes. In other examples of device 900 and device 1000, any other suitable temperatures may be distributed along the top cover 104 and bottom cover 106 of the respective enclosure.

The terms “an embodiment”, “embodiment”, “embodiments”, “the embodiment”, “the embodiments”, “one or more embodiments”, “some embodiments”, and “one embodiment” mean “one or more (but not all) embodiments” unless expressly specified otherwise.

The terms “including”, “comprising”, “having” and variations thereof mean “including but not limited to”, unless expressly specified otherwise.

The enumerated listing of items does not imply that any or all of the items are mutually exclusive, unless expressly specified otherwise.

The terms “a”, “an” and “the” mean “one or more”, unless expressly specified otherwise.

Devices that are in communication with each other need not be in continuous communication with each other, unless expressly specified otherwise. In addition, devices that are in communication with each other may communicate directly or indirectly through one or more intermediaries.

A description of an embodiment with several components in communication with each other does not imply that all such components are required. On the contrary a variety of optional components are described to illustrate the wide variety of possible embodiments. Further, although process steps, method steps, algorithms or the like may be described in a sequential order, such processes, methods, and algorithms may be configured to work in alternate orders. In other words, any sequence or order of steps that may be described does not necessarily indicate a requirement that the steps be performed in that order. The steps of processes described herein may be performed in any order practical. Further, some steps may be performed simultaneously.

When a single device or article is described herein, it will be readily apparent that more than one device/article (whether or not they cooperate) may be used in place of a single device/article. Similarly, where more than one device or article is described herein (whether or not they cooperate), it will be readily apparent that a single device/article may be used in place of the more than one device or article, or a different number of devices/articles may be used instead of the shown number of devices or programs. The functionality and/or the features of a device may be alternatively embodied by one or more other devices which are not explicitly described as having such functionality/features. Thus, other embodiments need not include the device itself.

At least certain operations that may have been illustrated in the figures show certain events occurring in a certain order. In alternative embodiments, certain operations may be performed in a different order, modified, or removed. Moreover, steps may be added to the above-described logic and still conform to the described embodiments. Further, operations described herein may occur sequentially or certain operations may be processed in parallel. Yet further, operations may be performed by a single processing unit or by distributed processing units.

The foregoing description of various embodiments has been presented for the purposes of illustration and description. It is not intended to be exhaustive or to be limited to the precise forms disclosed. Many modifications and variations are possible in light of the above teaching.

What is claimed is:

1. A device comprising:
a printed circuit board (PCB) comprising:
a top surface, and
a bottom surface opposite to the top surface;
circuitry disposed on one or more of the top surface or the bottom surface of the PCB; and
an enclosure to house the PCB, the enclosure comprising:
a top cover,
a bottom cover, and
one or more thermally-conductive poles, each of the one or more thermally-conductive poles thermally coupling the top cover and the bottom cover to cause heat transfer between the top cover and the bottom cover, and wherein each pole of the one or more thermally-conductive poles is arranged in a respective opening of the PCB such that there is no contact between any of the one or more thermally-conductive poles and the PCB.

2. The device of claim 1, wherein the top cover and the bottom cover are further thermally coupled using a thermal interface material (TIM).

3. The device of claim 1, further comprising:
for each respective pole of the one or more thermally-conductive poles, at least one thermal interface material (TIM) layer disposed between the respective pole and one of: the top cover or the bottom cover.

4. The device of claim 1, wherein at least one of the one or more thermally-conductive poles extends in a direction perpendicular to each of the top surface and the bottom surface of the PCB.

5. The device of claim 1, wherein:
the circuitry comprises a plurality of electrical components, and
the one or more thermally-conductive poles are disposed within the enclosure based on each respective location of at least one of the plurality of electrical components.

6. The device of claim 1, wherein the one or more thermally-conductive poles are disposed within the enclosure based on one or more PCB footprint constraints.

7. The device of claim 1, wherein each respective pole of the one or more thermally-conductive poles comprises:
a first pedestal coupled to the top cover,
a second pedestal coupled to the bottom cover, and
thermal interface material (TIM) to thermally couple the first pedestal and the second pedestal.

8. The device of claim 7, wherein:
the first pedestal is of a first length and extends in a first direction perpendicular to each of the top surface and the bottom surface of the PCB,
the second pedestal is of a second length and extends in a second direction that is opposite to and colinear with the first direction, and
the first length and the second length are different.

9. The device of claim 1, wherein the enclosure comprises a thermally-conductive material.

10. A printed circuit board (PCB) comprising:
a top surface,
a bottom surface opposite to the top surface;
circuitry disposed on one or more of the top surface or the bottom surface; and
one or more openings through which respective thermally-conductive poles of one or more thermally-conductive poles of an enclosure are to be arranged such that there is no contact between any of the one or more thermally-conductive poles and the PCB, wherein each opening of the one or more openings extends from the bottom surface to the top surface, and wherein:
the PCB is to be enclosed in an enclosure comprising:
a top cover,
a bottom cover, and
the one or more thermally-conductive poles, wherein each of the one or more thermally-conductive poles thermally coupling the top cover and the bottom cover to cause heat transfer between the top cover and the bottom cover.

11. The PCB of claim 10, wherein at least one of the one or more openings are configured to accept a thermally-conductive pole extending in a direction perpendicular to each of the top surface and the bottom surface of the PCB.

12. The PCB of claim 10, wherein:
the circuitry comprises a plurality of electrical components, and
the one or more openings are disposed based on each respective location of at least one of the plurality of electrical components.

13. The PCB of claim 10, wherein the one or more openings are disposed within the enclosure based on one or more PCB footprint constraints.

14. An enclosure comprising:
a top cover,
a bottom cover, and
one or more thermally-conductive poles to be arranged in one or more openings of a printed circuit board (PCB) to be enclosed by the enclosure, the one or more thermally-conductive poles arranged such that there is no contact between any of the one or more thermally-conductive poles and the PCB, wherein each of the one or more thermally-conductive poles thermally coupling the top cover and the bottom cover to cause heat transfer between the top cover and the bottom cover, and wherein:
the PCB comprises:
a top surface,
a bottom surface,
the one or more openings, and
circuitry disposed on one or more of the top surface or the bottom surface.

15. The enclosure of claim 14, wherein the top cover and the bottom cover are further thermally coupled using a thermal interface material (TIM).

16. The enclosure of claim 14, wherein at least one of the one or more thermally-conductive poles extends in a direction perpendicular to each of the top surface and the bottom surface of the PCB.

17. The enclosure of claim 14, wherein the enclosure further comprises:
for each respective pole of the one or more thermally-conductive poles, at least one thermal interface material (TIM) layer disposed between the respective pole and one of: the top cover or the bottom cover.

18. The enclosure of claim 14, wherein each respective pole of the one or more thermally-conductive poles comprises:
a first pedestal coupled to the top cover,
a second pedestal coupled to the bottom cover, and
thermal interface material (TIM) to thermally couple the first pedestal and the second pedestal.

19. The enclosure of claim 18, wherein:
the first pedestal is of a first length and extends in a first direction perpendicular to each of the top surface and the bottom surface of the PCB,
the second pedestal is of a second length and extends in a second direction that is opposite to and colinear with the first direction, and
the first length and the second length are different.

20. The enclosure of claim 14, wherein the enclosure comprises thermally-conductive material.
